(19) United States
(12) Patent Application Publication
(10) Pub. No.: US 2008/0054485 A1
(43) Pub. Date: Mar. 6, 2008

(54) SEMICONDUCTOR DEVICE AND FABRICATING METHOD THEREOF

(76) Inventor: Jae-Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/846,311

(22) Filed: Aug. 28, 2007

(30) Foreign Application Priority Data
Aug. 29, 2006 (KR) 10-2006-0082549

(51) Int. Cl. H01L 23/52; H01L 21/00

(52) U.S. Cl. 257/774; 438/109; 257/E21.001; 257/E23.141

(57) ABSTRACT

A semiconductor device includes a semiconductor device formed with at least two holes to which devices can be inserted; a plurality of devices inserted into the holes of the semiconductor substrate; connecting electrodes electrically connecting the plurality of devices; and a pad part connecting signals between the plurality of connected devices and to external devices.

The present application claims priority under 35 U.S.C. 119 to Korean Patent Application No. 10-2006-0082549 (filed on Aug. 29, 2006), which is hereby incorporated by reference in its entirety.

### BACKGROUND

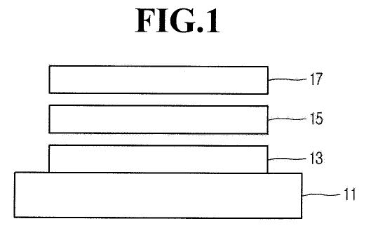

Example FIG. 1 is a concept view of a semiconductor device in a system in a package (SiP) configuration fabricated by means of a related art fabricating method of semiconductor devices. As shown in Example FIG. 1, the semiconductor device in the SiP configuration comprises an interposer 11, a first device 13, a second device 15, and a third device 17.

The first to third devices 13, 15, and 17 may be any one selected from CPU, SRAM, DRAM, Flash Memory, Logic LSI, Power IC, Control IC, Analog LSI, MM IC, CMOS RF-IC, Sensor Chip, and MEMS Chip, etc., by way of example. Connecting means for signal connections between the respective devices are formed between the first device 13 and the second device 15, and between the second device 15 and the third device 17, respectively.

As one of the connecting means for signal connections between the respective devices, a through via may be used. The through via, which is a via formed that penetrates through the device, can perform the function of electrically connecting the corresponding device to the device stacked above. Also, the through via can also perform the function of electrically connecting the corresponding device to the device stacked below.

However, the semiconductor device in a system in a package (SiP) configuration has a problem in vertically arranging the devices which may have different sizes and also has difficulty in heat dissipation of the devices stacked in the middle thereof.

### SUMMARY

Embodiments relate to a semiconductor device that includes a semiconductor substrate having a top surface and a bottom surface with at least two cavities extending from the top surface towards the bottom surface with a respective device located within each cavity, wherein each device is stacked in a SiP configuration. The device also includes at least one connecting electrode, each connecting electrode electrically connecting an adjacent pair of devices.

Embodiments relate to a method of fabricating a semiconductor device. In accordance with this method, the following steps are performed: inserting each of a plurality of devices into the a respective one of a plurality of holes in a semiconductor substrate; and forming at least one connecting electrode electrically connecting the plurality of devices; and forming a pad part configured to provide an external signal connection for the plurality of connected devices.

Embodiments relate to a semiconductor device that includes a semiconductor substrate having at least two holes in which devices can be inserted and a plurality of devices respectively located within each of the holes of the semiconductor substrate. The device also includes at least one connecting electrode electrically connecting the plurality of devices; and a pad part configured to provide an external signal connection for the plurality of connected devices.

### DRAWINGS

Example FIG. 1 is a concept view of a semiconductor device in a system in a package (SiP) configuration fabricated by means of a fabricating method of semiconductor device of the related art.

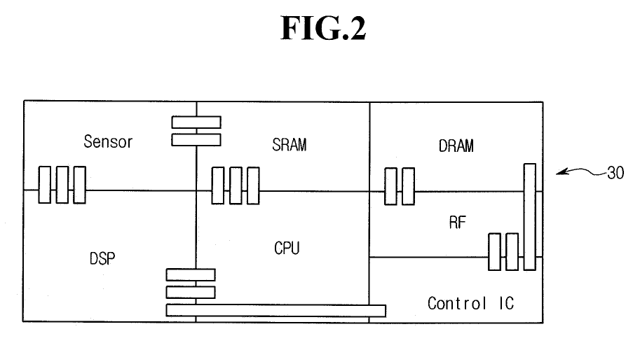

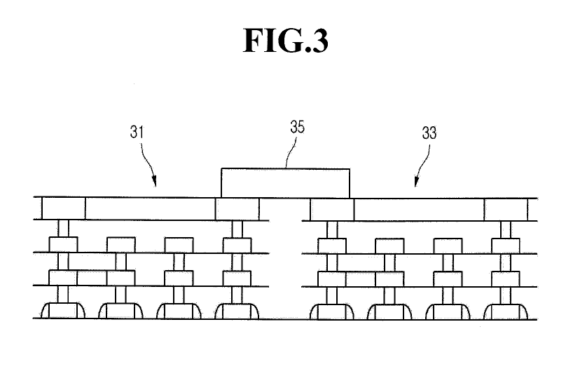

Example FIGS. 2 and 3 are concept views of a system by interconnection (SbI).

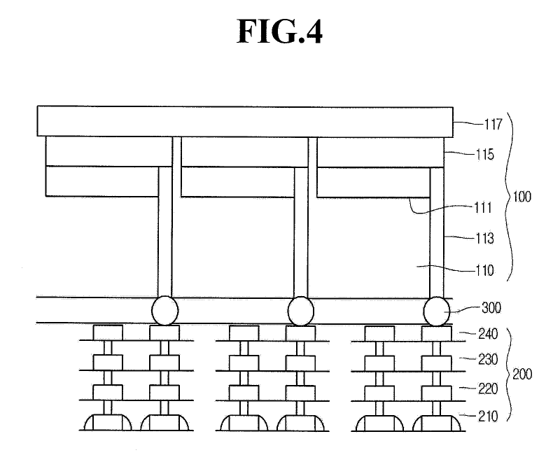

Example FIG. 4 is a concept view of an image sensor stacked in a SiP configuration according to embodiments.

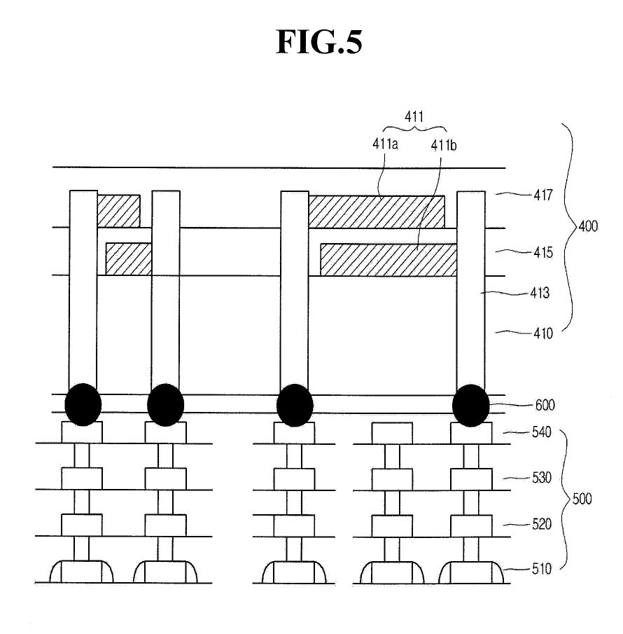

Example FIG. 5 is a concept view of a semiconductor device provided with a capacitor device stacked in a SiP configuration according to embodiments.

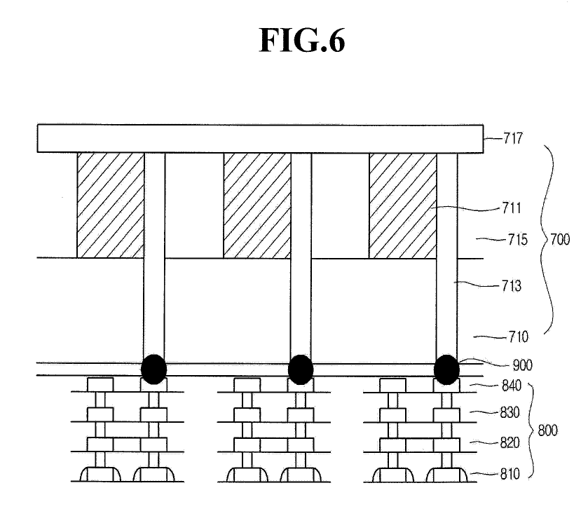

Example FIG. 6 is a concept view of a semiconductor device provided with an inductor device stacked in a SiP configuration according to embodiments.

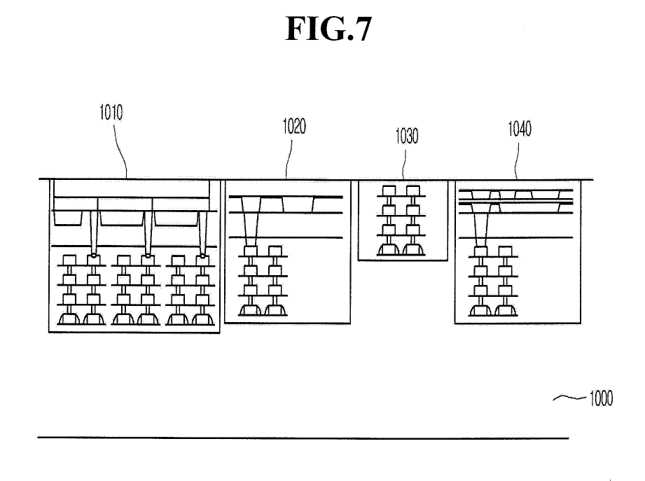

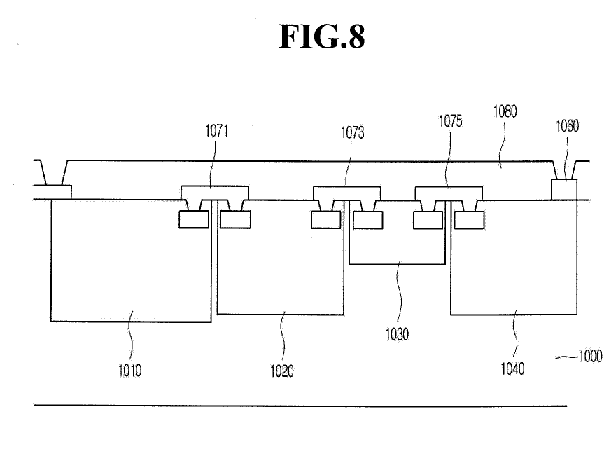

Example FIGS. 7 and 8 are concept views of the examples of the semiconductor device where devices are integrated by combining a SiP configuration and a SbI configuration according to embodiments.

### DESCRIPTION

In the description of embodiments, when each layer (film), area, pad, pattern or structures is described to be formed “on/above” or “below/under” each layer (film), area, pattern or structures, it can be understood as the case that each layer (film), area, pattern or structure is formed by being in direct contact with each layer (film), area, pad, pattern or structures and it can further be understood as the case that other layers (film), areas, pad, patterns or structures are additionally formed therebetween. Therefore, the meanings should be judged according to the technical idea of the embodiment.

Hereinafter, the embodiments will be described in detail with reference to the accompanying drawings.

Example FIGS. 2 and 3 are concept views of a system by interconnection (SbI). As shown in example FIGS. 2 and 3, the system by interconnection (SbI) integrates devices by connecting unit devices each fabricated in different wafers, such as CPU, SRAM, DRAM, Flash Memory, Logic Devices, Power IC, Control IC, and Sensor Chip, etc., by means of a connecting electrode.

The SbI shows the fabricating of a semiconductor device 30 integrated to perform the required functions, by fabricating a first device 31 and a second device 33 in separate semiconductor substrates, respectively, and then electrically connecting the first device 31 to the second device 33 through a connecting electrode 35, by way of example.

The example of the semiconductor device stacked in a SiP configuration is shown in example FIGS. 4 to 6. Example FIG. 4 shows an image sensor stacked in a SiP configuration, example FIG. 5 shows a semiconductor device provided with a capacitor device stacked in a SiP configuration, and example FIG. 6 shows a semiconductor device provided with an inductor device stacked in a SiP configuration.

Example FIG. 4 is a concept view of an image sensor stacked in a SiP configuration according to embodiments. The image sensor stacked in a SiP configuration as shown in example FIG. 4, comprises a first substrate 100, a second substrate 200, and a connecting electrode 300. The connecting electrode 300 connects a photo diode cell 111 formed on the first substrate 100 to a logic circuit part formed on the second substrate 200. The connecting electrode 300 is electrically connected to the photo diode cell 111 by means of a through via 113 formed on the first substrate 100. The connecting electrode 300 is electrically connected to a top metal forming the third metal layer 240 constituting the logic circuit part.

First, the photo diode cell 111 is formed on the upper region of the semiconductor substrate 110 then the through via 113 connected to the photo diode cell 111 and penetrating through the semiconductor substrate 110 is formed.

The through via 113 can be formed by sequentially performing a patterning process, an etching process, and a metal forming process, etc. on the semiconductor substrate 110. Such processes are already well-known and the detailed description thereof will be omitted herein.

At this time, the through via 113 may be formed of any material selected from materials such as W, Cu, Al, Ag, and Au, etc. The through via 113 can be deposited by means of a CVD method, a PVD method, an evaporation method, and an ECP method, etc. Also, as the barrier metal of the through via 113, TaN, Ta, TiN, Ti, and TiSiN, etc. can be used and they may be formed by means of a CVD method, a PVD method, and an ALD method, etc.

A color filter 115 may then be formed on the photo diode cell 111 and a protective layer 117 formed on the color filter 115.

Also, a second substrate 200 comprising a transistor layer 210, a first metal layer 220, a second metal layer 230, and a third metal layer 240 is fabricated as well.

The transistor layer 210 and the first, second and third metal layers 220, 230, and 240 can form a logic circuit part for signal processing. Herein, the case where the first, second, and third metal layers 220, 230, and 240 are formed is shown by way of example, but the number of the metal layers can be reduced or be further increased depending on the design thereof.

A transistor is formed on the transistor layer 210 corresponding to a photo diode cell 111 region provided in the first substrate 100. The transistor is formed to correspond to the photo diode cell 111 region and it can be formed in one, two, four, or various figures depending on design choices. Because the region of the photo diode cell 111 can be more largely formed as compared to the related art, there is no need to restrict the number of the transistors to be formed. Accordingly, a degree of freedom capable of forming a great number of transistors in order to improve the characteristics of the image sensor is provided, if necessary. Also, there is no need to use a fine circuit process in order to constitute a logic circuit part.

With the image sensor as shown in Example FIG. 4, the logic circuit part is not positioned on the photo diode cell 111. As described above, since the photo diode cell 111 can be directly exposed to the external light without additional obstacles, the resulting image sensor has an advantage that a separate micro lens is not required.

Example FIG. 5 is a concept view of a semiconductor device provided with a capacitor device stacked in a SiP configuration according to embodiments.

The semiconductor device provided with a capacitor devices stacked in a SiP configuration as shown in Example FIG. 5, comprises a first substrate 400, a second substrate 500, and a connecting electrode 600. The connecting electrode 600 connects a capacitor cell 411 formed on the first substrate 400 to a logic circuit part formed on the second substrate 500. The connecting electrode 600 is electrically connected to the capacitor cell 411 by means of a through via 413 formed on the first substrate 400. The connecting electrode 600 is electrically connected to a top metal forming the third metal layer 540 constituting the logic circuit part.

The capacitor cell 411 can comprise a upper electrode 411a and a lower electrode 411b. The through via 413 is connected to the upper electrode 411a and the lower electrode 411b constituting the capacitor cell 411, and the formation position thereof can be variously modified as appropriate.

The process fabricating the first substrate 400 will be briefly described as follows. First, a lower electrode 411b, an insulating layer 415, and an upper electrode 411a are formed in the semiconductor substrate 410. A separate insulating layer can be formed between the semiconductor substrate 410 and the lower electrode 411b.

The through via 413 connected to the capacitor cell 411 and penetrating through the semiconductor substrate 410 is then formed. The through via 413 can be formed by sequentially performing a patterning process, an etching process, a metal forming process, and a CMP process, etc. on the semiconductor substrate 410. Such processes are already well-known and the detailed description thereof will be omitted herein.

At this time, the upper electrode 411a and the lower electrode 411b constituting the capacitor cell 411, and the through via 413 may be formed of any material selected from materials such as W, Cu, Al, Ag, and Au, etc. The capacitor cell 411 and the through via 413 can be deposited by means of a CVD method, a PVD method, an evaporation method, and an ECP method, etc. Also, as the barrier metal of the capacitor cell 411 and the through via 413, TaN, Ta, TiN, Ti, and TiSiN, etc. can be used and they may be formed by means of a CVD method, a PVD method, and an ALD method, etc.

A protective layer 417 may then be formed on the capacitor cell 411.

Also, as shown in the figure, a second substrate 500 comprising a transistor layer 510, a first metal layer 520, a second metal layer 530, and a third metal layer 540 is fabricated as well.

The transistor layer 510 and the first, second and third metal layers 520, 530, and 540 can form a logic circuit part for signal processing. Herein, the case where the first, second, and third metal layers 520, 530, and 540 are formed is shown by way of example, but the number of the metal layers can be reduced or be further increased depending on the design thereof.

Example FIG. 6 depicts a concept view of a semiconductor device provided with an inductor device stacked in a SiP configuration according to embodiments.

The semiconductor device provided with an inductor as shown in Example FIG. 6, comprises a first substrate 700, a second substrate 800, and a connecting electrode 900. The connecting electrode 900 connects an inductor cell 711 formed on the first substrate 700 to a RF device circuit part formed on the second substrate 800. The connecting electrode 900 is electrically connected to the inductor cell 711 by means of a through via 713 formed on the first substrate 700. The connecting electrode 900 is electrically connected to a top metal forming the third metal layer 840 constituting the RF device circuit part.

First, an insulating layer 715 is formed on the semiconductor substrate 710 and a patterning for forming an inductor is performed. After performing an etching process, the inductor barrier metal deposition and the inductor metal layer filling are performed. A CMP is performed on the resultant product thereof, making it possible to form an inductor cell 711.

Then the through via 713 connected to the inductor cell 711 and penetrating through the semiconductor substrate 710 is formed. The through via 713 can be formed by sequentially performing a patterning process, an etching process, a metal forming process, and a CMP process, etc. on the semiconductor substrate 710. Such processes are already well-known and the detailed description thereof will be omitted herein.

The inductor cell 711 and the through via 713 may be formed of any material selected from materials such as W, Cu, Al, Ag, and Au, etc. The inductor cell 711 and the through via 713 can be deposited by means of a CVD method, a PVD method, an evaporation method, and an ECP method, etc. Also, as the barrier metal of the inductor cell 711 and the through via 713, TaN, Ta, TiN, Ti, and TiSiN, etc. can be used and they may be formed by means of a CVD method, a PVD method, and an ALD method, etc. A protective layer 717 may then be formed on the inductor cell 711.

Also, a second substrate 800 comprising a transistor layer 810, a first metal layer 820, a second metal layer 830, and a third metal layer 840 is fabricated.

The transistor layer 810 and the first, second and third metal layers 820, 830, and 840 can form a RF device circuit part for signal processing. Herein, the case where the first, second, and third metal layers 820, 830, and 840 are formed is shown by way of example, but the number of the metal layers can be reduced or be further increased depending on the design thereof.

Example FIGS. 7 and 8 are concept views of the examples of the semiconductor device where devices are integrated by combining a SiP configuration and a SbI configuration according to embodiments.

Such a semiconductor device comprises a semiconductor device 1000 formed with at least two holes to which devices can be inserted; and first, second, third, and fourth devices 1010, 1020, 1030, and 1040 inserted into the holes of the semiconductor substrate 1000. Also, the semiconductor device comprises connecting electrodes 1071, 1073, and 1074 electrically connecting the first, second, third, and fourth devices 1010, 1020, 1030, and 1040; and a pad part 1060 connecting signals between the first, second, third, and fourth devices 1010, 1020, 1030, and 1040 and the external. In example, FIG. 7 the four devices inserted into the semiconductor device 1000 are shown by way of example, and one of ordinary skill will recognize that the number of devices to be inserted can vary.

The first, second, third, and fourth devices 1010, 1020, 1030, and 1040 inserted to the holes of the semiconductor substrate 1000 may be devices stacked in a SiP configuration or separate devices not stacked. For example, the first, second, third, and fourth devices 1010, 1020, 1030, and 1040 may be devices independently selected from the group including an image sensor stacked in a SiP configuration, devices stacked in a SiP configuration and having a capacitor cell, devices stacked in a SiP configuration and having an inductor cell, and CPU, SRAM, DRAM, Flash Memory, Logic Devices, Power IC, Control IC, and Sensor Chip.

Also, the surfaces of the first, second, third, and fourth devices 1010, 1020, 1030, and 1040 inserted into the holes of the semiconductor substrate 1000 may be such that they are the same in view of their height. Thus, a protective layer 1080 formed on the connecting electrodes 1071, 1073, and 1075 may further be included. The connecting electrodes 1071, 1073, and 1075 may be formed of materials selected from the groups including Al, Ti/TiN/Al/Ti/TiN, Ti/Al/Ti/TiN, Ti/Al/TiN, Ti/TiN/Al/Ti, Ti/TiN/Al/TiN, Cu, and TaN/Cu/TaN.

The thickness of the metal layer formed of Al or Cu may be formed at approximately 500 to approximately 10000 Å, and the thickness of Ti or TiN, Ta, and TaN may be formed at about approximately 20 to approximately 1000 Å. The metal layer may be formed by means of a PVD method or a CVD method, etc. Also, the protective layer 1080 may be formed by means of an electric furnace, a CVD method, and a PVD method, etc. and may be formed of materials such as SiO₂, BPSG, TEOS, and SiN, etc. Also, the thickness of the protective layer 1080 may be formed from approximately 0.3 to approximately 5 μm.

A fabricating method of a semiconductor device as just described includes the steps of providing a semiconductor device 1000 formed with at least two holes to which devices can be inserted; inserting a plurality of devices 1010, 1020, 1030, and 1040 into the holes of the semiconductor device 1000; and forming connecting electrodes 1071, 1073, and 1075 electrically connecting the plurality of devices 1010, 1020, 1030, and 1040 and a pad part 1060 connecting signals between the plurality of connected devices 1010, 1020, 1030, and 1040 and any external devices.

Furthermore, an additional step may be performed of forming a protective layer 1080 on the connecting electrodes 1071, 1073, and 1075, wherein the protective layer 1080 is removed for the region where the pad part 1060 is formed.

With this semiconductor device and the fabricating method thereof, devices stacked in a system in a package (SiP) configuration or a separate device are connected in a system by interconnection (SbI) scheme, making it possible to more efficiently form an integrated device. Also, the problem of heat dissipation of the device stacked in the middle of the stacked device in a SiP configuration can also be easily solved. Another advantage realized is that of simplifying a fabricating process, improving a fabricating efficiency, and implementing a highly integrated device of a system level.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate having at least two holes in which devices can be inserted;
a plurality of devices respectively located within each of the holes of the semiconductor substrate;
at least one connecting electrode electrically connecting the plurality of devices; and
a pad part configured to provide an external signal connection for the plurality of connected devices.

2. The semiconductor device of claim 1, wherein each connecting electrode electrically connects an adjacent pair of the plurality of devices.

3. The semiconductor device of claim 1, wherein the plurality of devices include at least one device stacked in a SiP configuration.

4. The semiconductor device of claim 1, wherein each of the plurality of devices is a device stacked in a SiP configuration.

5. The semiconductor device of claim 1, wherein a top surface of each of the plurality of devices are substantially at the same height.

6. The semiconductor device of claim 1, wherein one or more of the devices are independently selected from the group including: an image sensor stacked in a SiP configuration, devices stacked in a SiP configuration and having a capacitor cell, devices stacked in a SiP configuration and having an inductor cell, CPU, SRAM, DRAM, Flash Memory, Logic Devices, Power IC, Control IC, and Sensor Chip.

7. The semiconductor device of claim 1, further comprising a protective layer formed on the at least one connecting electrode.

8. The semiconductor device of claim 1, wherein the at least one connecting electrode is formed of materials selected from the groups: Al, Ti/TiN/Al/Ti/TiN, Ti/Al/Ti/TiN, Ti/Al/TiN, Ti/TiN/Al/Ti, Ti/TiN/Al/TiN, Cu, and TaN/Cu/TaN.

9. A method of fabricating a semiconductor device comprising:
inserting each of a plurality of devices into the a respective one of a plurality of holes in a semiconductor substrate; and
forming at least one connecting electrode electrically connecting the plurality of devices; and
forming a pad part configured to provide an external signal connection for the plurality of connected devices.

10. The method of claim 9, further comprising:
providing the semiconductor substrate formed with at least two holes in which respective ones of the plurality of devices can be inserted.

11. The method of claim 9, further comprising:
forming, in the semiconductor substrate, two holes in which respective ones of the plurality of devices can be inserted.

12. The method of claim 9, wherein at least one of the devices inserted into the semiconductor substrate is stacked in a SiP configuration.

13. The method of claim 9, wherein each of the devices inserted into the semiconductor substrate is stacked in a SiP configuration.

14. The method of claim 9, wherein a top surface of each of the plurality of devices are substantially at the same height.

15. The method of claim 9, wherein one or more of the plurality of devices are independently selected from the group including: an image sensor stacked in a SiP configuration, devices stacked in a SiP configuration and having a capacitor cell, devices stacked in a SiP configuration and having an inductor cell, and CPU, SRAM, DRAM, Flash Memory, Logic Devices, Power IC, Control IC, and Sensor Chip.

16. The method of claim 9, further comprising:
forming a protective layer on at least one connecting electrode.

17. The method of claim 9, wherein the at least one connecting electrode is formed of materials selected from the groups including Al, Ti/TiN/Al/Ti/TiN, Ti/Al/Ti/TiN, Ti/Al/TiN, Ti/TiN/Al/Ti, Ti/TiN/Al/TiN, Cu, and TaN/Cu/TaN.

18. A semiconductor device comprising:
a semiconductor substrate having a top surface and a bottom surface with at least two cavities extending from the top surface towards the bottom surface;
a respective device located within each cavity, wherein each device is stacked in a SiP configuration; and
at least one connecting electrode, each connecting electrode electrically connecting an adjacent pair of devices.

19. The semiconductor device of claim 18, further comprising:
a pad configured to provide an external signal connection for the respective devices.

20. The semiconductor device of claim 18, wherein a top surface of each respective device is substantially a same height as the top surface of the semiconductor substrate.
